(19) United States
(12) Patent Application Publication
(10) Pub. No.: US 2008/0102617 A1
(43) Pub. Date: May 1, 2008

(54) Method of Fabricating Flash Memory Device

(76) Inventor: Chan Sun Hyun, Icheon-si (KR)

Correspondence Address: MARSHALL, GERSTEIN & BORUN LLP, 233 S. WACKER DRIVE, SUITE 6300, SEARS TOWER, CHICAGO, IL, 60606, US

(21) Appl. No.: 11/771,315

(22) Filed: Jun. 29, 2007

(30) Foreign Application Priority Data
Oct. 31, 2006 (KR) 2006-106315

(51) Int. Cl. H01L 21/3205

(52) U.S. Cl. 438/593; 257/E21.294

(57) ABSTRACT

A method of fabricating a flash memory device is disclosed herein. The method of fabricating a flash memory device includes the steps of forming a gate insulating film, a first conductive film and a nitride film over a semiconductor substrate in which a cell region and a peri region are defined, etching the nitride film, the first conductive film, the gate insulating film and part of the semiconductor substrate to form trenches, forming an isolation film in each trench, primarily etching the isolation films of the cell region and the peri region, removing the nitride film, secondarily etching the isolation film of the cell region, thirdly etching the isolation films of the cell region and the peri region, and forming a dielectric film and a second conductive film on the entire surface including the isolation films.

### CROSS-REFERENCE TO RELATED APPLICATION

The priority benefit of Korean patent application number 2006-106315, filed on Oct. 31, 2006, is hereby claimed, and its disclosure is hereby incorporated herein by reference in its entirety.

### BACKGROUND OF THE INVENTION

The present invention relates to a method of fabricating a flash memory device.

General flash manufacture method is as following.

A gate insulating film, a first conductive film for a floating gate and a nitride film are sequentially formed over a semiconductor substrate in which a cell region and a peri region are defined. Trenches are formed by etching the nitride film, the first conductive film, the gate insulating film, and part of the semiconductor substrate by means of an etch process using a mask film pattern or a photoresist film pattern. The inside of each trench is filled with an insulating film for an isolation film. The insulating film is polished by a process such as Chemical Mechanical Polishing (CMP) until the nitride film pattern is partially exposed. Thus, an isolation film is formed within the trenches.

The nitride film pattern is removed. In this case, the height of the isolation film is maintained as high as the nitride film pattern. To prevent the active portion of the peri region from being damaged in a subsequent gate etch process, the isolation film of the cell region is removed to a specific thickness by an etch process using a mask having an opened cell region, thus lowering the step. The whole isolation film of the cell region and the peri region is then etched to a specific depth in order to lower the height of the isolation film. A dielectric film is formed on the isolation film and the first conductive film, and a gate formation process is then carried out.

In this general method, however, the isolation film of the peri region has a profile in which it is tilted toward the inside of the transistor and the height of the isolation film is higher than 250 angstrom. Thus, a gate bridge phenomenon in which conductive material remains at the boundary of the isolation film and the active portion is generated.

### SUMMARY OF THE INVENTION

Accordingly, the present invention addresses one or more of the above problems, and fabricates devices with one or more advantages, including, but not limited to improved yield and electrically stabilized characteristics, by decreasing a step in an isolation film between a cell region and a peri region in such a manner that the height of the isolation film formed in the peri region is lowered and a gate is patterned in order to facilitate the etch process of the isolation film.

In an aspect of the present invention, there is provided a method of fabricating a flash memory device that includes the steps of forming a gate insulating film, a first conductive film and a nitride film over a semiconductor substrate in which a cell region and a peri region are defined, etching the nitride film, the first conductive film, the gate insulating film and part of the semiconductor substrate to form trenches, forming an isolation film in the trenches, primarily etching the isolation films of the cell region and the peri region, removing the nitride film, secondarily etching the isolation film of only the cell region, optionally thirdly etching the isolation films of the cell region and the peri region, and forming a dielectric film and a second conductive film on the entire surface including the isolation films.

### BRIEF DESCRIPTION OF THE DRAWINGS

FIGS. 1A to 1D are cross-sectional views illustrating a method of fabricating a flash memory device according to the present invention

### DESCRIPTION OF SPECIFIC EMBODIMENTS

A specific embodiment according to the present invention will be described with reference to the accompanying drawings.

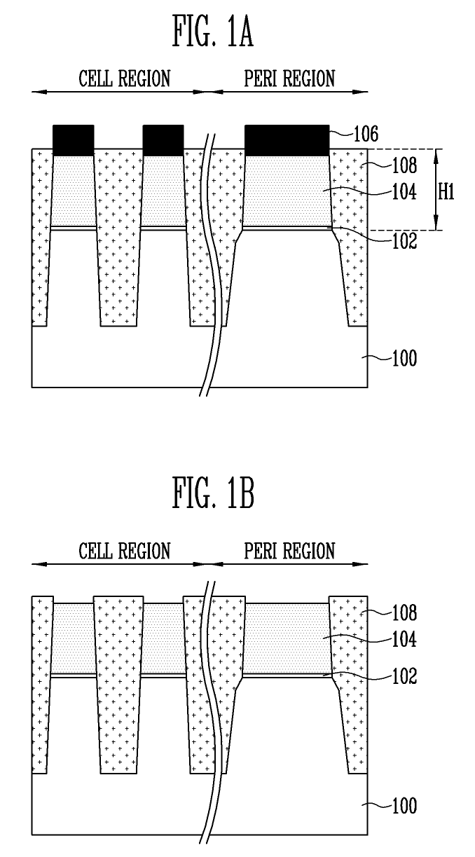

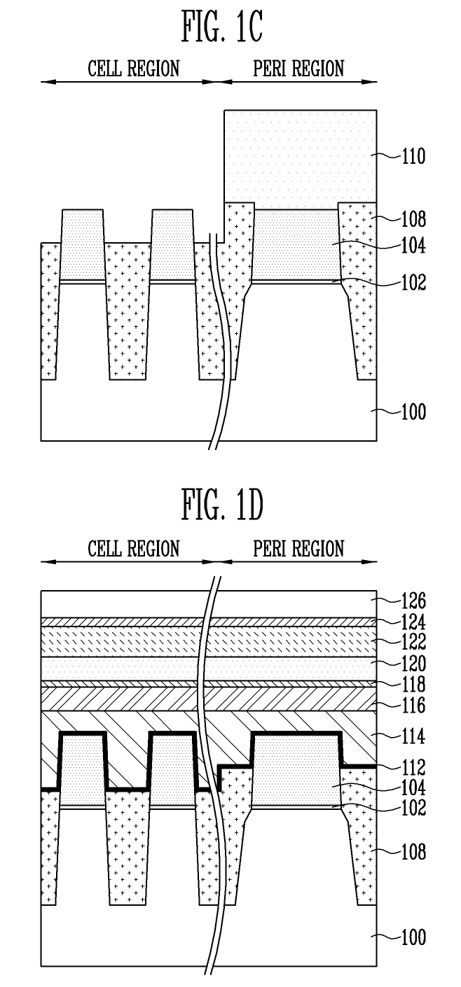

FIGS. 1A to 1D are cross-sectional views illustrating a method of fabricating a flash memory device according to the present invention.

Referring to FIG. 1A, a gate insulating film 102, a first conductive film 104 for a floating gate and a nitride film 106 are sequentially formed over a semiconductor substrate 100 in which a cell region and a peri region are defined. Trenches are formed by etching the nitride film 106, the first conductive film 104, the gate insulating film 102, and part of the semiconductor substrate 100 by means of an etch process using a mask film pattern or a photoresist film pattern. The inside of each trench is filled with an insulating film for an isolation film 108. The insulating film is polished by a process such as Chemical Mechanical Polishing (CMP) until the nitride film pattern 106 is partially exposed. Thus, an isolation film 108 is formed within the trenches.

An etch process for lowering the height of the isolation film 108 overall is performed before removing the nitride film pattern 106. The etch process is carried out until the height H1 from the active top of the peri region to the top of the isolation film 108 is in a range of about 200 to about 400 angstrom. The etch process of the isolation film 108 can be performed by using a dry or wet etch process. In the case where the dry etch process is performed, argon (Ar) gas preferably is used to minimize the loss of the first conductive film 104, and the Ar gas preferably is injected at a flow rate of 100 sccm or less. Further, in the dry etch process, bias power preferably 500W or below, for example ranging from 100 to 500 W, which is low compared with bias power in previously-known methods, preferably is applied, and source power ranging from 100 to 600 W preferably is applied. Meanwhile, in the case where the wet etch process is performed, preferably HF or Buffed Oxide Etchant (BOE) is used. In this case, it is advantageous to use HF having an etch selectivity higher than that of BOE with respect to the conductive film.

Referring to FIG. 1B, the nitride film pattern 106 is removed. The nitride film pattern 106 is preferably removed by a wet etch process using H₃PO₄. Accordingly, the first conductive film 104 is exposed and the isolation film 108 is higher than the first conductive film 104.

Referring to FIG. 1C, a mask pattern 110 for shielding the peri region and opening the cell region is formed over the isolation film 108 and the first conductive film 104. The isolation film 108 of the cell region is partially removed by an etch process using the mask pattern 110, thus lowering the height of the isolation film 108.

Referring to FIG. 1D, the mask pattern 110 is removed. There occurs a step in the height of the isolation film 108 between the cell region and the peri region. The height of the isolation film 108 of the peri region is greater than that of the isolation film 108 of the cell region. Furthermore, the height of the isolation film 108 of the peri region from the active top can be in a range of about −100 to about 150 angstrom. A third etching step can be used to etch the isolation films of the cell region and the peri region after secondarily etching the isolation film of only the cell region. A dielectric film 112 is formed on the entire surface including the isolation film 108 and the first conductive film 104.

A second conductive film 114 for a control gate, a metal film 116, a first hard mask film 118, a second hard mask film 120, a carbon film 122, a third hard mask film 124 and a gate mask film 126 are sequentially formed over the dielectric film 112. The metal film 116 preferably is formed of WSix. The first hard mask film 118 preferably is formed of SiON. The second hard mask film 120 preferably is comprised of a Tetra Ethyl Ortho Silicate (TEOS) layer. The carbon film 122 preferably is formed of amorphous carbon. The third hard mask film 124 preferably is formed of SiON. To form a gate, a gate mask film 126 is formed on the third hard mask film 124.

As described above, according to the present invention, before a nitride film pattern is removed the height of an isolation film is lowered primarily. After the nitride film pattern is removed, the height of the isolation film is lowered secondarily. Accordingly, the gate bridge phenomenon occurring at the boundary of the isolation film and the active can be prevented.

Although the foregoing description has been made with reference to the specific embodiment, it is to be understood that changes and modifications of the present invention may be made by the person of ordinary skill in the art without departing from the spirit and scope of the present invention and appended claims.

What is claimed is:

1. A method of fabricating a flash memory device, comprising the steps of:
forming, sequentially, a gate insulating film, a first conductive film and a nitride film over a semiconductor substrate in which a cell region and a peri region are defined;
etching the nitride film, the first conductive film, the gate insulating film and part of the semiconductor substrate to form trenches;
forming an isolation film in the trenches;
primarily etching the isolation films of the cell region and the peri region;
removing the nitride film;
secondarily etching the isolation film only of the cell region; and
forming a dielectric film and a second conductive film on the entire surface including the isolation films.

2. The method of claim 1, wherein the primary etch process is performed until a height from an active top of the peri region to a top of the isolation film is in a range of about 200 to about 400 angstrom.

3. The method of claim 1, wherein the primary etch process is performed by using a dry etch process or a wet etch process.

4. The method of claim 3, wherein the dry etch process is performed by using argon (Ar) gas.

5. The method of claim 4, wherein the argon (Ar) gas is injected at a flow rate of 100 sccm or less.

6. The method of claim 3, wherein the dry etch process is performed by applying bias power in a range of about 100 to about 500 W.

7. The method of claim 3, wherein the dry etch process is performed by applying source power in a range of about 100 to about 600 W.

8. The method of claim 3, wherein the wet etch process is performed by using HF or BOE.

9. The method of claim 1, wherein the nitride film is removed by performing a wet etch process using H₃PO₄.

10. The method of claim 1, further comprising thirdly etching the isolation films of the cell region and the peri region after secondarily etching the isolation film of only the cell region, wherein the third etch process is performed so that a height of the isolation film of the peri region on the basis of an active top is in a range of about −100 to about 150 angstrom.
